(19) United States
(12) Patent Application Publication
(10) Pub. No.: US 2025/0364171 A1
(43) Pub. Date: Nov. 27, 2025

(54) MAGNETIC COMPONENT AND COIL DEVICE

(71) Applicant: Panasonic Automotive Systems Co., Ltd., Kanagawa (JP)

(72) Inventors: Shinichiro KOKUBO, Kanagawa (JP); Hayata ONAGA, Kanagawa (JP)

(21) Appl. No.: 19/169,816

(22) Filed: Apr. 3, 2025

(30) Foreign Application Priority Data
May 21, 2024 (JP) 2024-082372

(51) Int. Cl. H01F 27/10; H05K 7/20

(52) U.S. Cl. CPC H01F 27/10; H05K 7/20445

(57) ABSTRACT

A magnetic component includes a component main body from which heat is to be dissipated, a box-shaped member whose one face is opened, and a potting material having thermal conductivity and being filled into the box-shaped member. The box-shaped member includes a plate-like member having thermal conductivity. The box-shaped member includes an opening part, a top surface facing the opening part, side surfaces extending from the top surface to the opening part, and a heat dissipation part provided at an end on a side of the opening part of the side surface. The top surface of the box-shaped member is thermally connected to a first principal surface of the component main body. The box-shaped member functions as a heat dissipation pathway through which heat is transported from the component main body to the heat dissipation part via the top surface by thermal conductance.

### CROSS-REFERENCE TO RELATED APPLICATIONS

This application is based upon and claims the benefit of priority from Japanese Patent Application No. 2024-082372, filed May 21, 2024, the entire contents of which are incorporated herein by reference.

### FIELD

The present disclosure relates generally to a magnetic component and a coil device.

### BACKGROUND

Conventionally, an in-vehicle charger of an electric vehicle and a power conversion device (coil device) such as a DC-DC converter have been known. In such devices, when power conversion of large-current or high-voltage power is performed, heat generation in a magnetic component such as an inductor or a transformer becomes large. For this reason, a technique of efficiently dissipating heat from a magnetic component of a coil device has been demanded.

For example, a patent literature JP 6268509 B2 discloses a reactor device that includes a coil for power factor improvement or smoothing. For the reactor device, the patent literature discloses a technique of dissipating heat by filling a metal case storing a transformer core and a heat dissipation plate with a potting resin material, and thereby transferring heat generated in the transformer core to the metal case via the heat dissipation plate.

In such a technique, an in-vehicle coil device has been demanded to be downsized in order to cope with the limitation on a space in the vehicle where the coil device is installed.

Therefore, there is a demand for downsizing a magnetic component of the coil device.

### SUMMARY

A magnetic component according to one aspect of the present disclosure includes a component main body from which heat is to be dissipated, a box-shaped member with a box shape whose one face is opened, and a potting material having thermal conductivity. The box-shaped member includes a plate-like member having thermal conductivity. The box-shaped member includes: an opening part, a top surface facing the opening part, side surfaces extending from the top surface to the opening part, and a heat dissipation part provided at an end on a side of the opening part of one or more of the side surfaces. The potting material is filled into the box-shaped member from the opening part. The top surface of the box-shaped member is thermally connected to a first principal surface of the component main body. The box-shaped member functions as a heat dissipation pathway through which heat is transported from the component main body to the heat dissipation part via the top surface by thermal conductance.

### BRIEF DESCRIPTION OF THE DRAWINGS

FIG. 1 is a front view illustrating an example of a configuration of a transformer assembly having a heat dissipation structure according to an embodiment;

FIG. 2 is a top view illustrating an example of a configuration of the transformer assembly illustrated in FIG. 1;

FIG. 3 is a left side view illustrating an example of a configuration of the transformer assembly illustrated in FIG. 1;

FIG. 4 is a cross-sectional view illustrating an example of a configuration of the transformer assembly illustrated in FIG. 1;

FIG. 5 is a perspective view illustrating an example of a configuration of a metal case illustrated in FIG. 1;

FIG. 6 is a perspective view illustrating an example of a configuration of the metal case illustrated in FIG. 1;

FIG. 7 is a diagram for explaining an example of an assembly process of a transformer assembly according to an embodiment;

FIG. 8 is a diagram for explaining an example of an assembly process of a transformer assembly according to an embodiment; and

FIG. 9 is a diagram for explaining downsizing of a transformer assembly that is performed by a heat dissipation structure according to an embodiment.

### DETAILED DESCRIPTION

Hereinafter, embodiments of a heat dissipation structure, a magnetic component, a coil device (power conversion device), a vehicle, and a manufacturing method according to the present disclosure will be described with reference to the drawings.

In the description of the present disclosure, components having the same or approximately the same functions as those described earlier with reference to already-described drawings are assigned the same reference numerals, and the description will be sometimes omitted as appropriate. Even in a case where the same or approximately the same parts are illustrated, dimensions and ratios between components illustrated in the drawings sometimes vary depending on the drawing.

Moreover, from the viewpoint of ensuring visibility of drawings, only major components in the description of each diagram are assigned the reference numerals, and components having the same or approximately the same functions as those described earlier with reference to already-described drawings are sometimes not assigned reference numerals.

In the description of the present disclosure, wordings such as orthogonal, horizontal, vertical, parallel, the same, equivalent, and the same position are not limited to strict orthogonal, horizontal, vertical, parallel, the same, equivalent, and the same position, and include states that can be regarded as orthogonal, horizontal, vertical, parallel, the same, equivalent, and the same position.

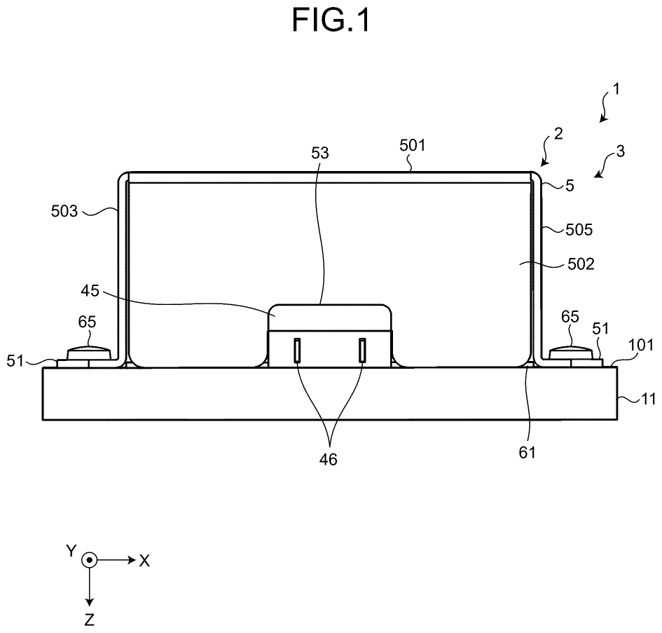

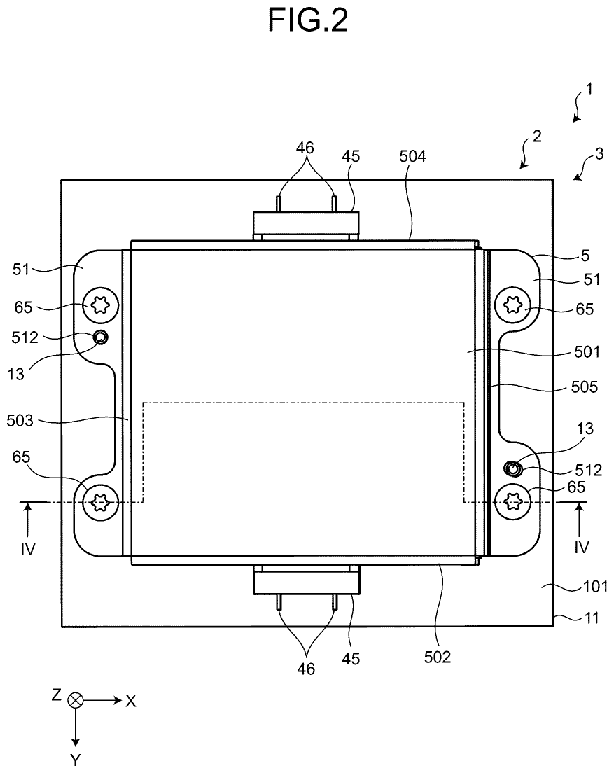

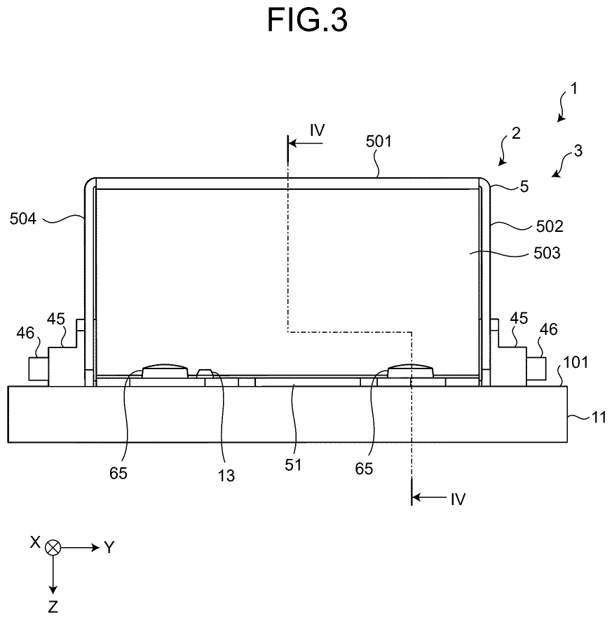

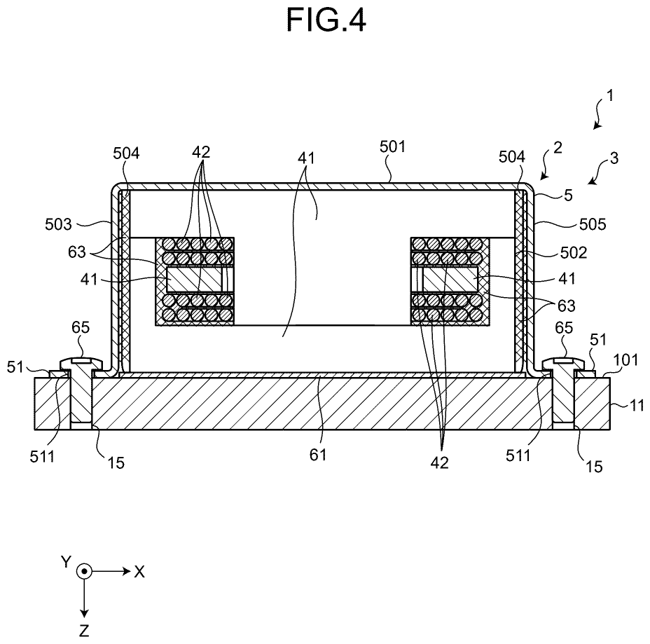

FIG. 1 is a front view illustrating an example of a configuration of a transformer assembly 2 having a heat dissipation structure 3 according to an embodiment. FIG. 2 is a top view illustrating an example of a configuration of the transformer assembly 2 illustrated in FIG. 1. FIG. 3 is a left side view illustrating an example of a configuration of the transformer assembly 2 illustrated in FIG. 1. FIG. 4 is a cross-sectional view illustrating an example of a configuration of the transformer assembly 2 illustrated in FIG. 1.

FIGS. 1 to 4 each exemplify the transformer assembly 2 in a state of being installed in an in-vehicle charger 1. FIG. 4 exemplifies a cross section illustrating a IV-IV surface (Z-X plane) in FIGS. 2 and 3 that is viewed from a paper surface lower side in FIG. 2 or a paper surface right side in FIG. 3 (+Y side).

In the description of the present disclosure, a direction from the transformer assembly 2 toward a housing 11 of the in-vehicle charger 1 is defined as a +Z direction. Directions, which extend along a cooling surface 101 of the housing 11 of the in-vehicle charger 1 and are orthogonal to the Z direction, are defined as an X direction and a Y direction. Thus, the cooling surface 101 is a surface parallel to an X-Y plane.

The in-vehicle charger 1 according to the present disclosure is an example of a power conversion device (coil device). The power conversion device is installed in a vehicle (movable body) such as an electric vehicle, for example. Alternatively, the power conversion device may be installed in another device of a movable body such as a charging device of a charging station, playing equipment, or a permanent power supply, for example. The in-vehicle charger 1 may be a power conversion device that converts alternating-current power supplied from an external single-phase or three-phase power supply, into direct-current power, and supplies the converted direct-current power to a load equipped in a vehicle. This load may be a battery, an inverter, a motor, or various electric components, for example.

As a movable body in which the in-vehicle charger 1 (coil device) according to the present disclosure is to be installed, various movable bodies configured to be able to be driven or drive their accessories (electric components) using power from a battery, such as a passenger automobile, a freight vehicle, a shared vehicle, a motorbike, an electric kickboard, a construction machine, a farm machine, or an airplane, for example, can be used as appropriate. As the electric component, for example, a navigation device, au audio device, an air conditioner, a power window, a defogger, an electronic control unit (ECU), a global positioning system (GPS) module, or a camera can be used. The battery of the movable body is only required to be able to store power for driving a motor for moving (main electric motor) and electrical components that are provided in the movable body, and the like. An optional battery such as a lithium-ion battery, a nickel-metal hydride battery, or an all-solid-state battery can be used as appropriate.

The in-vehicle charger 1 according to the present disclosure may be provided with a noise filter that prevents the entry of noise from an external alternating-current power supply to the in-vehicle charger 1, and the leak of noise from the in-vehicle charger 1 to the alternating-current power supply, for example (removes noise). At the subsequent stage of the noise filter, a power converter circuit is provided. The power converter converts, into direct-current power, alternating-current power supplied from an external single-phase or three-phase alternating-current power supply via the noise filter, and outputs the converted direct-current power to a battery. Such a power converter circuit is provided with a power factor correction (PFC) circuit that generates direct-current voltage by performing rectifying and smoothing on alternating-current voltage from the external alternating-current power supply from which noise has been removed by the noise filter, for example. At the subsequent stage of the PFC circuit in the power converter circuit, a DC-DC converter circuit is provided. The DC-DC converter circuit generates direct-current voltage with an optional voltage by converting the direct-current voltage generated by the PFC circuit, again to alternating-current voltage, and then performing rectifying and smoothing.

Components of the in-vehicle charger 1 such as the noise filter, the PFC circuit, and the DC-DC converter circuit include magnetic components such as various inductors such as a transformer, a transformer-integrated printed-circuit-board, or a choke, a reactor, or an assembly (for example, the transformer assembly 2) of these. In the present disclosure, a device such as a power conversion device in which these magnetic components are provided will be referred to as a coil device. The in-vehicle charger 1, and components of the in-vehicle charger 1 including the noise filter, the PFC circuit, and the DC-DC converter circuit (DCDC converter) each serve as an example of the coil device. A coil device in which a magnetic component including the transformer is provided may be referred to as a transformer device. Alternatively, the coil device and the transformer device (i.e., a coil device including a transformer device) may be collectively referred to as a transformer/coil device. Hereinafter, the description of a coil device according to the present disclosure will be continued using the in-vehicle charger 1 as an example. In the in-vehicle charger 1, when power conversion of large-current or high-voltage power is performed, heat generation in a magnetic component becomes large. For this reason, a technique of efficiently dissipating heat from a magnetic component of the in-vehicle charger 1 is demanded.

The magnetic components of the in-vehicle charger 1 according to the present disclosure are provided in the cooling surface 101 of the housing 11 of the in-vehicle charger 1 for the cooling thereof. As illustrated in FIGS. 1 to 4, the transformer assembly 2 serving as an example of a magnetic component of according to the present disclosure is provided on the cooling surface 101 of the housing 11 in a state where a part or all of components such as a transformer 4 (component main body) and a metal case 5 are integrally assembled (modularized). The transformer assembly 2 is detachably fixed onto the cooling surface 101 of the housing 11 by a fixing member 65 such as a screw, for example. In addition, fixing of the transformer assembly 2 onto the cooling surface 101 of the housing 11 may be undetachable bonding that uses welding or an adhesive. The housing 11 according to an embodiment is an example of an external cooling member.

As illustrated in FIG. 4, on the side (−Z side) of the cooling surface 101 of the housing 11 of the in-vehicle charger 1 according to the present disclosure, a hole 15 for fixing the transformer assembly 2 using the fixing member 65 is provided. As illustrated in FIGS. 2 and 3, on the side (−Z side) of the cooling surface 101 of the housing 11, a positioning pin 13 formed into a shape such as a cylindrical shape or a conical shape is provided. The positioning pin 13 defines the position of the transformer assembly 2 on the cooling surface 101 of the housing 11. The positioning pin 13 extends from the cooling surface 101 in a direction (−the Z direction) of getting away from the cooling surface 101 on the side of the cooling surface 101 of the housing 11.

The magnetic components of the in-vehicle charger 1 according to the present disclosure and the cooling surface 101 of the housing 11 are thermally connected. The state of thermally-connected refers to a configuration in which thermal exchange can be performed. Thermal transport between the magnetic components of the in-vehicle charger 1 and the cooling surface 101 of the housing 11 is implemented by thermal conductance, for example, but may be performed by another configuration in addition to or in place of thermal conductance. The thermal transport may be performed via another component of the in-vehicle charger 1.

The housing 11 of the in-vehicle charger 1 according to the present disclosure is formed of a metal material such as a die casting, for example. The housing 11 of the in-vehicle charger 1 forms a liquid cooling system cooling mechanism that uses cooling liquid such as antifreeze liquid, as working fluid. A flow path (not illustrated) of cooling liquid that extends along a direction going along the cooling surface 101 (for example, horizontal direction) is formed inside the housing 11 of the in-vehicle charger 1. Thus, a flow path running inside one surface (cooling surface) is formed inside the housing 11 of the in-vehicle charger 1.

The cooling mechanism of the in-vehicle charger 1 according to the present disclosure is only required to be configured to be able to execute thermal exchange between the cooling surface 101 of the housing 11 and the outside of the housing 11, for example, and the cooling system is not limited to the liquid cooling (water-cooling) system that uses cooling liquid such as antifreeze liquid or water, as working fluid, and another optional cooling system can be applied as appropriate. In one example, a cooling mechanism of a forced air cooling system or a naturally cooling system that uses optional gas such as working fluid may be applied. In one example, a cooling mechanism that uses an optional cooling medium such as hydrofluorocarbon (HFC), as working fluid may be applied. A flow path of working fluid such as cooling liquid that is formed inside the housing 11 of the in-vehicle charger 1 according to the present disclosure may branch in at least two directions within one surface going along the cooling surface. On the other hand, the flow path does not branch in a direction orthogonal to the cooling surface. In other words, in a case where the housing 11 of the in-vehicle charger 1 includes an intersection point where flow paths in at least two directions intersect with each other, while each flow path extends from the intersection point in a direction parallel to the cooling surface, each flow path does not extend in a direction orthogonal to the cooling surface. In this manner, a cooling mechanism of the entire system of the in-vehicle charger 1 according to the present disclosure is formed by a flow path running only one surface inside the housing 11.

As illustrated in FIG. 4, the transformer assembly 2 serving as an example of the magnetic component according to the present disclosure includes the transformer 4, the metal case 5, a thermal conductance member 61, and a potting material 63.

As illustrated in FIG. 4, the transformer 4 serving as an example of a component main body of the magnetic component according to the present disclosure includes a plurality of cores 41 and a plurality of winding wires 42. The winding wires 42 is disposed within a space formed by the cores 41. The winding wires 42 include a primary side winding wire (coil) and a secondary side winding wire (coil). As illustrated in FIGS. 1 and 2, the transformer 4 serving as an example of a component main body of the magnetic component according to the present disclosure includes a plurality of connectors 45.

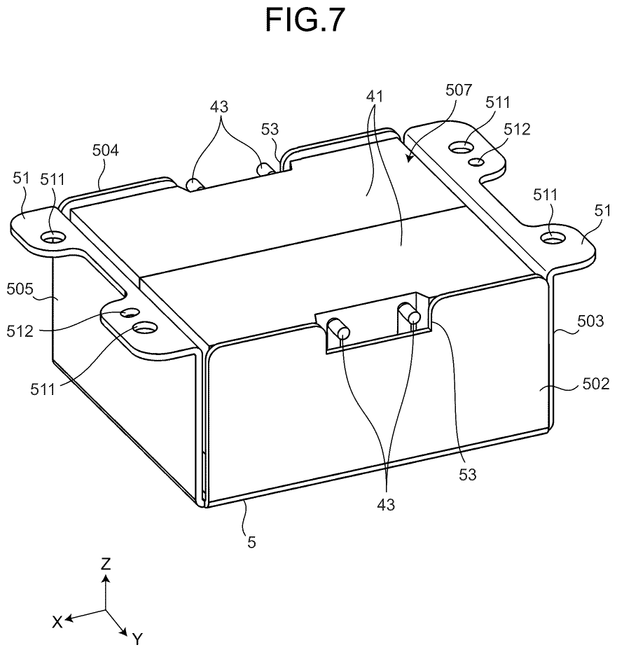

Each of the connectors 45 electrically connects the transformer 4 and another electronic component of the in-vehicle charger 1. In the transformer 4, each of the connectors 45 is electrically connected to one of the winding wires 42. The connectors 45 each includes a pair of blades 46 electrically connected to a pair of leads 43 (refer to FIG. 7) of each of the winding wires 42 of the transformer 4. The pair of leads 43 of each of the winding wires 42 corresponds to parts extending from both ends of each of the winding wires 42, and includes a lead extending from a “winding start” of each of the winding wires 42, and a lead extending from a “winding end”. One of the connectors 45 is related to a circuit configuration including the transformer 4 of the in-vehicle charger 1, and electrically connected to a primary side circuit configuration. The other one of the connectors 45 is electrically connected to a secondary side circuit configuration.

As illustrated in FIGS. 1 and 2, the leads 43 (refer to FIG. 7) on an input side and an output side of a −Z side winding wire 42 in FIG. 4 are electrically connected to the blades 46 on an input side and an output side of the connector 45 that are provided to pass through a notch 53 of a front surface 502 of the metal case 5. As illustrated in FIG. 2, the leads 43 on an input side and an output side of a +Z side winding wire 42 in FIG. 4 are electrically connected to the blades 46 on an input side and an output side of the connector 45 that are provided to pass through a notch 53 of a rear surface 504 of the metal case 5.

The heat dissipation structure 3 according to the present disclosure can be applied to various coils formed by in-phase-winding the winding wire 42 such as a copper wire around the core 41 that uses a magnetic material. Thus, the number of winding wires 42 in the magnetic component according to the present disclosure can be changed as appropriate. In one example, the heat dissipation structure 3 according to the present disclosure may be applied to a three-phase four-wire common mode choke coil including four winding wires.

In the magnetic component according to the present disclosure, the shape of the core 41 may be an optional shape, and various core shapes can be used as appropriate. The core 41 may include one core 41, or as illustrated in FIG. 4, may be formed by assembling (binding) the cores 41.

In the example in FIG. 4, the core 41 is formed by assembling one T-type core, two U-type cores, and one C-type core (shunt core).

The T core is provided on the side of a top surface 501 of the metal case 5 (the −Z side). As illustrated in FIG. 4, the T core has a T-shaped cross-section, and includes a rectangular flat plate part parallel to the X-Y plane, and a columnar part extending from a central part of the flat plate part toward the +Z side in a columnar shape. The two U cores are provided on the side of the front surface 502 of the metal case 5 (+Y side), and the side of the rear surface 504 (−Y side), on the opposite side of the top surface 501 of the T core (the +Z side). As illustrated in FIG. 4, each U core has a U-shaped cross-section, and includes a rectangular flat plate part parallel to the X-Y plane, and a recess part in which a central part of the flat plate part is recessed from the −Z side toward the +Z side in a semicircular columnar shape. In a case where the two U cores are assembled, the assembled two U cores present the shape of a rectangular flat plate hollowed out into a columnar shape. Accordingly, in a case where one T core and two U cores are assembled, a cylindrical space extending in the Z direction is formed inside the assembly.

In a cylindrical space formed by one T core and two U cores, an R core formed into an annular flat plate is arranged. The winding wires 42 of the transformer 4 are formed into an annular shape, and arrayed in the Z direction via the R core.

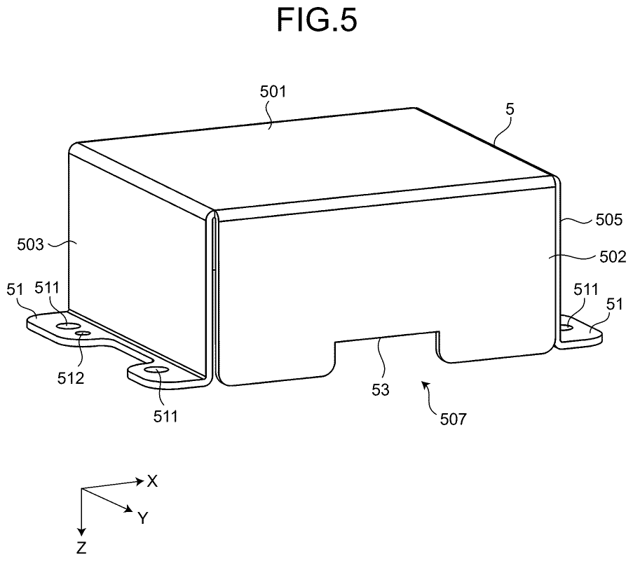

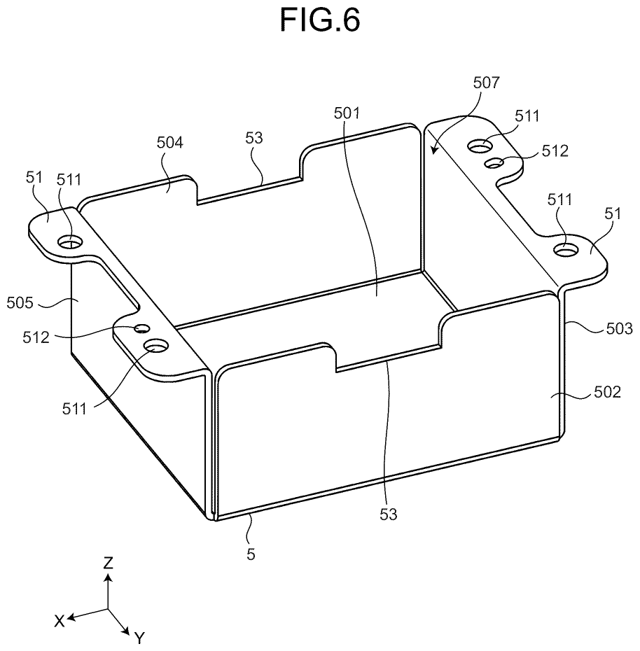

Each of FIGS. 5 and 6 is a perspective view illustrating an example of a configuration of the metal case 5 in FIG. 1. The metal case 5 is formed using a plate-like member formed of a material having a heat dissipation property (thermal conductivity). The metal case 5 is formed into a box shape by folding a plate-like member made of a material such as metal, for example, that has a high heat dissipation property (thermal conductivity), by performing bending work (for example, press work), for example. Specifically, the metal case 5 is a box-shaped member that is formed into a box shape whose one face is opened, and covers the transformer 4 serving as an example of the component main body. As an example, the metal case 5 is formed of a metal material such as aluminum or die casting. The material of the metal case 5 is not limited to metal, and for example, the metal case 5 may be formed of a carbon-based material such as graphite. The metal case 5 according to an embodiment is an example of a box-shaped member.

As illustrated in FIGS. 5 and 6, the metal case 5 includes the top surface 501, the front surface 502, a left side surface 503, the rear surface 504, and a right side surface 505. In the description of the present disclosure, in a case where a distinction is not made among the front surface 502, the left side surface 503, the rear surface 504, and the right side surface 505, these are sometimes collectively referred to as “side surfaces”.

The top surface 501 is a plate-like part constituting the −Z side of the metal case 5. The front surface 502 is a plate-like part extending in the +Z direction from the end on a +Y side of the top surface 501. The left side surface 503 is a plate-like part extending in the +Z direction from the end on a-X side of the top surface 501. The rear surface 504 is a plate-like part extending in the +Z direction from the end on a-Y side of the top surface 501. The right side surface 505 is a plate-like part extending in the +Z direction from the end on a +X side of the top surface 501.

In the metal case 5, two adjacent side surfaces are bonded by welding or an adhesive (not illustrated), or a gap therebetween is filled with a seal material (not illustrated). The adhesive and the seal material preferably have thermal conductivity. The end on the +Z side of each side surface of the metal case 5 forms an opening part 507. In other words, the metal case 5 is formed into a box shape having a bottom surface corresponding to the top surface 501, and opening toward the +Z side.

At least two adjacent parts of the top surface 501, the front surface 502, the left side surface 503, the rear surface 504, and the right side surface 505 may be formed as mutually different members, and then bonded by welding or an adhesive (not illustrated).

At least two adjacent parts of the top surface 501, the front surface 502, the left side surface 503, the rear surface 504, and the right side surface 505 may be formed by performing, for example, bending work (for example, press work).

The front surface 502 may be a plate-like part extending toward the +X side from the end on a Y+ side of the left side surface 503 extending in the +Z direction from the end on the −X side of the top surface 501.

As another an example, the front surface 502 may be formed by a plate-like first part extending toward the +X side from the end on the Y+ side of the left side surface 503 extending in the +Z direction from the end on the −X side of the top surface 501, and a plate-like second part extending toward the −X side from the end on the Y+ side of the right side surface 505 extending in the +Z direction from the end on the +X side of the top surface 501.

As another an example, the front surface 502 may be formed by a plate-like first part extending toward the +X side from the end on the Y+ side of the left side surface 503 extending in the +Z direction from the end on the −X side of the top surface 501, a plate-like second part extending toward the −X side from the end on the Y+ side of the right side surface 505 extending in the +Z direction from the end on the +X side of the top surface 501, and a plate-like third part extending in the +Z direction from the end on the +Y side of the top surface 501.

As illustrated in FIGS. 1 to 6, in each of the left side surface 503 and the right side surface 505 of the metal case 5, a fixing part 51 (heat dissipation part) is formed by performing, for example, bending work (for example, press work). Specifically, the fixing part 51 formed in the left side surface 503 is a plate-like part extending toward the −X side along the X-Y plane from the end on the +Z side of the left side surface 503. Specifically, the fixing part 51 formed in the right side surface 505 is a plate-like part extending toward the +X side along the X-Y plane from the end on the +Z side of the right side surface 505.

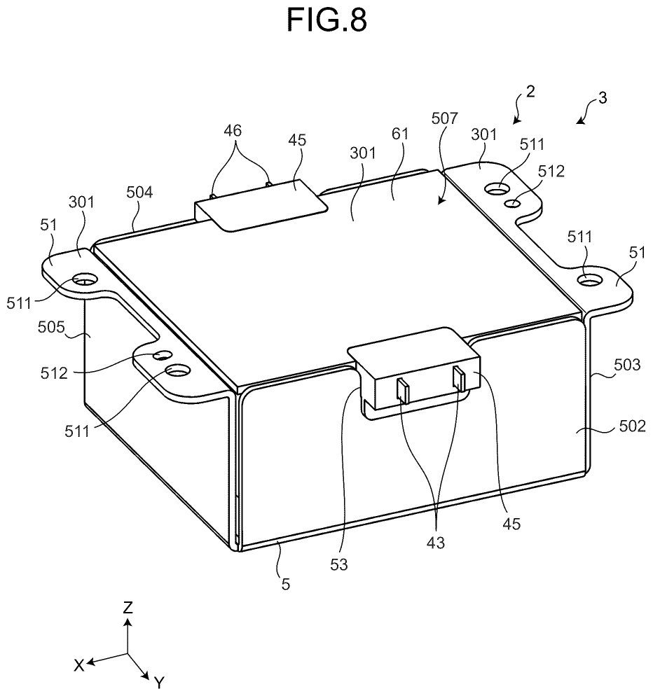

As illustrated in FIGS. 4 to 6, in each of the fixing parts 51, a hole 511 is provided. The hole 511 of each of the fixing parts 51 has an identical position on the X-Y plane to a corresponding hole 15 of the housing 11 in a state where the transformer assembly 2 is arranged at a predetermined position on the cooling surface 101 of the housing 11. In one example, the transformer assembly 2 is fastened to the housing 11 by the fixing member 65 such as a screw that is inserted into the hole 15 of the housing 11 while penetrating the hole 511 of each of the fixing parts 51, in a state of being arranged at a predetermined position on the cooling surface 101 of the housing 11. As a result, the fixing part 51 of the metal case 5 is thermally connected to the cooling surface 101 of the housing 11. Thus, a surface on the opposite side (the +Z side) of the top surface 501 of the fixing part 51 forms a heat dissipation surface 301 (refer to FIG. 8) of the transformer assembly 2.

The thermal conductance member 61 may be provided between the fixing part 51 of the metal case 5 and the cooling surface 101. The thermal conductance member 61 may be part of the thermal conductance member 61 provided between the core 41 of the transformer and the cooling surface 101, and may be another thermal conductance member 61 independently formed using a thermal interface material. The position and the number of the holes 511 in each of the fixing part 51 can be changed as appropriate.

As illustrated in FIGS. 2, 5 and 6, a hole 512 is formed in each of the fixing parts 51. The hole 512 of each of the fixing parts 51 defines a predetermined position where the transformer assembly 2 is provided on the cooling surface 101 of the housing 11, by fitting with the corresponding positioning pin 13 of the housing 11. The hole 512 provided in the fixing part 51 of the right side surface 505 is slightly larger than an external form of the positioning pin 13 of the housing 11. On the other hand, the hole 512 provided in the fixing part 51 of the left side surface 503 is larger than the hole 512 provided in the fixing part 51 of the right side surface 505. With this configuration, while defining the position of the transformer assembly 2 on the cooling surface 101 of the housing 11, it is possible to absorb a positional shift between the hole 511 of the metal case 5 and the hole 15 of the housing 11 that is attributed to a manufacturing variation, for example. The position and the number of the holes 512 in each of the fixing part 51 can be changed as appropriate.

As illustrated in FIGS. 1 and 5 to 6, in each of the front surface 502 and the rear surface 504 of the metal case 5, the notch 53 is formed by performing, for example, a cutting work or a punching work (for example, press work). Specifically, the notch 53 formed in the front surface 502 is a part recessed toward the −Z side along a Z-X plane from a part (for example, central part) of the end on the +Z side of the front surface 502. The notch 53 formed in the rear surface 504 is a part recessed toward the −Z side along the Z-X plane from a part (for example, central part) of the end on the +Z side of the rear surface 504.

As illustrated in FIGS. 1 and 2, in each of the notches 53 in the transformer assembly 2, the connector 45 passing through each of the notches 53 is arranged. Accordingly, the position and the size of each of the notches 53 are defined by the arrangement and the external form of the connector 45 of the transformer 4.

The arrangement of the fixing part 51 and the notch 53 onto each side surface in the metal case 5 can be changed as appropriate depending on the layout of the winding wire 42 of the transformer 4 (i.e., the position of the lead 43, the shape of the housing 11, and the arrangement of other components of the transformer assembly 2 of the in-vehicle charger 1.

In one example, the fixing parts 51 may be provided in any two parts of the side surfaces of the metal case 5, and the notches 53 may be provided in the other two parts.

As another an example, the notch 53 may be provided in any one part of the side surfaces of the metal case 5, and the fixing part 51 may be provided in at least one part of the other three parts. Thus, in the transformer assembly 2, two connectors 45 may be provided in one side surface of the metal case 5.

As another an example, both the fixing part 51 and the notch 53 may be provided in at least one part of the side surfaces of the metal case 5.

As another an example, the notch 53 may be provided as a hole in the top surface 501 of the metal case 5, or at another position at the end (part on the +Z side) of a side surface.

As illustrated in FIG. 4, in the transformer assembly 2, the transformer 4 is placed inside the metal case 5. The transformer assembly 2 has a structure that the periphery of the transformer 4 is surrounded by the box-shaped metal case 5 formed of a metal material. With this configuration, the metal case 5 can be caused to function as a case having a function of a shield of electromagnetic noise to the outside, heat dissipation from the transformer 4, and fixing to the housing 11.

The fixing of the metal case 5 to the housing 11 may be implemented by the in-vehicle charger 1 on the outside of the metal case 5, or a component of the transformer assembly 2. In one example, the transformer assembly 2 including the metal case 5 may be biased by an elastic member such as a spring (i.e., may be fixed by a spring retainer for the housing 11). Thus, in the metal case 5, the fixing part 51 is not an essential component, and may be omitted.

In one example, an end on the side of the opening part 507 of at least one side surface of the metal case 5 may function as a heat dissipation part to be thermally connected (for example, contacting the cooling surface 101 of the housing 11), in a state where the metal case 5 is attached to the housing 11. As another an example, the metal case 5 may be provided with a heat dissipation part similar to the fixing part 51 except that the holes 511 and 512 are not included, for example, in place of a fixing part. In this manner, the metal case 5 may be caused to function as a case having a function of a shield of electromagnetic noise to the outside, and heat dissipation from the transformer 4.

As another an example, the metal case 5 may be provided with a heat dissipation part in place of a fixing part, similar to the fixing part 51 except that the hole 511 is not included. In this case, because the hole 512 is formed, the heat dissipation part may function as a positioning part that defines the position of the metal case 5 on the housing 11. Thus, the metal case 5 may be caused to function as a case having a function of a shield of electromagnetic noise to the outside, heat dissipation from the transformer 4, and positioning to the housing 11.

A first principal surface (surface on the −Z side) of the transformer 4 is thermally connected to the top surface 501 of the metal case 5 by contacting the top surface 501, in a state of being placed inside the metal case 5. Specifically, the surface on the −Z side (first principal surface) of the core 41 (for example, T core) of the transformer 4 and the surface on the +Z side of the top surface 501 of the metal case 5 are thermally connected. With this configuration, heat from the core 41 is transferred to the fixing part 51 by thermal conductance, for example, through the top surface 501 to each side surface. Thus, in the transformer assembly 2, heat from the core 41 is routed to the surface extending along the cooling surface 101 of the housing 11, on which a horizontal flow path is formed (the surface on the +Z side of the fixing part 51).

The thermal conductance member 61 is formed of a thermal interface material (TIM). The thermal conductance member 61 is only required to be a member that decreases a contact thermal resistance by filling a gap between the transformer 4 and the cooling surface 101 of the housing 11, and can be formed in various forms such as a gap filler, a heat dissipation pad, thermal conductive grease, or potting.

As illustrated in FIG. 4, the thermal conductance member 61 is provided on a second principal surface on the side (the +Z side) of the opening part 507 of the metal case 5 of the transformer 4 in the transformer assembly 2. Thus, the thermal conductance member 61 is arranged between the transformer 4 and the cooling surface 101 of the housing 11 in a state where the transformer assembly 2 is arranged at the predetermined position on the cooling surface 101 of the housing 11. Specifically, the thermal conductance member 61 decreases the contact thermal resistance of a thermal transport pathway between the surface on the +Z side (second principal surface) of the core 41 (for example, U core) of the transformer 4 and the cooling surface 101 of the housing 11.

The potting material 63 is formed of a heat dissipation buffer material having at least a heat dissipation property (thermal conductivity) and an electrical insulation property. As illustrated in FIG. 4, the potting material 63 is filled inside the metal case 5. Thus, the potting material 63 functions as a heat dissipation pathway through which heat from the transformer 4 is transported. Specifically, the potting material 63 transports heat to the housing 11 from the core 41 and each of the winding wires 42 of the transformer 4 through the metal case 5 and the thermal conductance member 61. The potting material 63 is filled inside the metal case 5 from the opening part 507 in a state where the top surface 501 of the metal case 5 is positioned below the opening part 507 in a gravity direction, such as a state where the +Z direction corresponds to the gravity direction, for example. The potting material 63 is filled into a gap between the transformer 4 and the metal case 5. The potting material 63 is filled inside the transformer 4 such as a space between the cores 41 and a space between each the core 41 and each of the winding wires 42.

Each component of the transformer 4 is held by the potting material 63. Thus, the potting material 63 functions as a fixing member that fixes the transformer 4 placed inside the metal case 5. In a case where insulating processing is performed on each component of the transformer 4 or in a case where a sufficient insulating distance is ensured, the potting material 63 needs not have an electrical insulation property.

A manufacturing method of the transformer assembly 2 according to the present disclosure will be described with reference to the drawings.

Each of FIGS. 7 and 8 is a diagram for explaining an example of an assembly process of the transformer assembly 2 according to an embodiment.

Precedential to the assembly process, for example, by performing bending processing while forming the notch 53, on a plate-like member made of a material such as metal that has a high heat dissipation property (thermal conductivity), as illustrated in FIGS. 5 and 6, the box-shaped metal case 5 is formed. Then, a gap between adjacent side surfaces of the metal case 5 is filled by bonding the side surfaces by welding or an adhesive (not illustrated), or filling a seal material (not illustrated). These processes may be executed as part of the assembly process of the transformer assembly 2.

### First Pattern

First of all, in a state where the top surface 501 of the metal case 5 is positioned below the opening part 507 in the gravity direction (refer to FIG. 6), the transformer 4 is placed inside the metal case 5. Next, in a state where the transformer 4 is placed inside the metal case 5 (refer to FIG. 7), the potting material 63 is filled inside the metal case 5 from the opening part 507. After that, infiltration of the potting material 63 into the transformer 4 in the metal case 5 is waited.

### Second Pattern

First of all, in a state where the top surface 501 of the metal case 5 is positioned below the opening part 507 in the gravity direction (refer to FIG. 6), the potting material 63 is filled inside the metal case 5 from the opening part 507. Next, the transformer 4 is placed inside the metal case 5 filled with the potting material 63 (refer to FIG. 7). After that, infiltration of the potting material 63 into the transformer 4 in the metal case 5 is waited.

### Third Pattern

First of all, in a state where the top surface 501 of the metal case 5 is positioned below the opening part 507 in the gravity direction (refer to FIG. 6), the potting material 63 is filled inside the metal case 5 from the opening part 507. Next, the transformer 4 is placed inside the metal case 5 filled with the potting material 63 (refer to FIG. 7). After that, infiltration of the potting material 63 into the transformer 4 in the metal case 5 is waited. Then, after the potting material 63 is infiltrated into the transformer 4, the potting material 63 is additionally filled inside the metal case 5 from the opening part 507.

In this manner, the transformer 4 and the potting material 63 are placed inside the metal case 5 by any one of the first to third patterns. With this configuration, the transformer assembly 2 enters a state where each component of the transformer 4 is held by the potting material 63 in the metal case 5 and thermally connected to the metal case 5.

In one example, in a state where the top surface 501 of the metal case 5 is positioned below the opening part 507 in the gravity direction, the potting material 63 is filled up to the side of the opening part 507 (the +Z side) from an internal space of the transformer 4. The potting material 63 is filled up to the side of the opening part 507 (the +Z side) from the rear surface of the core 41 (for example, U core). The rear surface of the core 41 is a bottom surface of a recess part formed in the U core, for example. In a state where the top surface 501 of the metal case 5 is positioned below the opening part 507 in the gravity direction, the potting material 63 is filled up to the side of the opening part 507 (the +Z side) from an internal cylindrical space of the transformer 4 that is formed by the core 41.

In one example, in a state where the top surface 501 of the metal case 5 is positioned below the opening part 507 in the gravity direction, the potting material 63 is filled up to the side of the top surface 501 (the −Z side) from the notch 53 of the metal case 5. In a case where the potting material 63 is filled in a state where the connector 45 is attached to the notch 53 and a gap between the notch 53 and the connector 45 is filled using a seal material or an adhesive, the potting material 63 may be filled up to the side of the opening part 507 (the +Z side) from the notch 53.

In one example, in a state where the top surface 501 of the metal case 5 is positioned below the opening part 507 in the gravity direction, the potting material 63 is filled up to the side of the top surface 501 (the −Z side) from the end on the opening part 507 side of the metal case 5.

In the case of a later-filling method (first pattern) of filling the potting material 63 after the transformer 4 is arranged, while the potting material 63 can be filled up to a limit, the filling takes time. In the case of a first-filling method (second pattern) of filling the potting material 63 first and then arranging the transformer 4, while a time taken for the filling can be shortened as compared with that in the first pattern, it is difficult to fill the potting material 63 up to a limit. Accordingly, by the process of the third pattern obtained by combining the first-filling method and the later-filling method, it is preferable to make the potting material 63 fillable up to the limit while shortening a time taken for the filling.

After that, as illustrated in FIG. 8, the thermal conductance member 61 is assembled to the side of the opening part 507 of the core 41 of the transformer 4 (upward in the gravity direction). The surface on the opposite side (the +Z side) of the core 41 of the thermal conductance member 61 forms the heat dissipation surface 301 of the transformer assembly 2 together with the surface on the side (the +Z side) of the opening part 507 of the fixing part 51. In a state of being assembled to the transformer assembly 2, surfaces on the side (the +Z side) of the opening part 507 of the fixing part 51 and the thermal conductance member 61 are positioned within one surface (the X-Y plane). The surface on the side (the +Z side) of the opening part 507 of the connector 45 is positioned within the surface of the heat dissipation surface 301 or at a position closer to the side (the −Z side) of the top surface 501 then the heat dissipation surface 301.

The connector 45 of the transformer 4 may be assembled to the transformer 4 before the potting material 63 is filled, or may be assembled after the potting material 63 is filled.

After that, the heat dissipation surface 301 of the transformer assembly 2 assembled in this manner is assembled to the housing 11 in a direction facing the cooling surface 101 of the housing 11. Thus, an attachment direction (the +Z direction) in which the transformer assembly 2 according to the present disclosure is attached to the housing 11 and a filling direction (−the Z direction) of the potting material 63 in the assembly process of the transformer assembly 2 are different directions.

As described above, the heat dissipation structure 3 according to the present disclosure includes the metal case 5 that covers the transformer 4 serving as an example of the component main body, and is formed into a box shape whose one face is opened. With the heat dissipation structure 3, the transformer assembly 2 serving as an example of the magnetic component according to the present disclosure can perform heat dissipation by routing heat from the transformer 4 to the heat dissipation surface 301 by using the metal case 5. In a state where the transformer assembly 2 is assembled to the housing 11, the heat dissipation surface 301 faces the cooling surface 101 of the housing 11 and is thermally connected thereto.

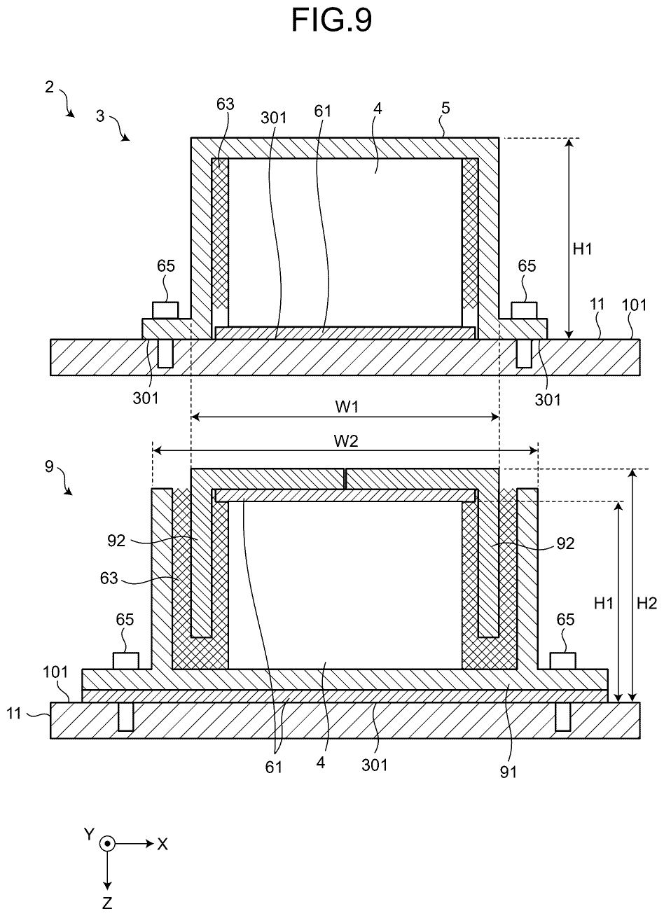

FIG. 9 is a diagram for explaining downsizing of the transformer assembly 2 that is performed by the heat dissipation structure 3 according to an embodiment. FIG. 9 exemplifies a transformer assembly 9 according to a comparative example that does not include the heat dissipation structure 3 according to the present disclosure, together with the transformer assembly 2 having the heat dissipation structure 3 according to the present disclosure.

As described above, by being filled from the side of the opening part 507 in a state where the top surface 501 of the metal case 5 is positioned below the opening part 507 in the gravity direction, the potting material 63 can be filled also into a gap between the top surface 501 of the metal case 5 and the core of the transformer 4 placed inside the metal case 5. Thus, in the heat dissipation structure 3 according to the present disclosure, the top surface 501 of the metal case 5 and the transformer 4 placed inside the metal case 5 are thermally connected directly or via the potting material 63. With this configuration, heat from a part distant from the cooling surface 101 (i.e., the side (the −Z side) of the top surface 501 of the transformer 4) can be routed up to the heat dissipation surface 301 (the surface on the +Z side of the fixing part 51) by the metal case 5.

On the other hand, in the transformer assembly 9 according to the comparative example, a metal case 91 includes a bottom surface (flat plate part on the +Z side) and a side surface. Thus, the metal case 91 according to the comparative example is provided with an opening part at a part corresponding to the top surface 501 according to the present disclosure (part on the −Z side), in a state where the transformer assembly 9 is assembled to the housing 11. In such a configuration, the bottom surface of the metal case 91 is thermally connected to the cooling surface 101 of the housing 11 via the thermal conductance member 61. The potting material 63 is filled from the side of the opening part (the −Z side) in a state where the bottom surface of the metal case 91 (part on the +Z side) is positioned below the opening part in the gravity direction.

In the transformer assembly 9 according to the comparative example, it is necessary to provide a heat dissipation plate 92 in addition to the metal case 91 for heat dissipation from the side of the opening part of the transformer 4 (the −Z side). The heat dissipation plate 92 is a metal plate formed into an L-shape, for example, but may be a metal plate formed into a pointed U-shape, or may be a metal plate formed into a box shape whose one face is opened. The heat dissipation plate 92 is thermally connected to the side of the opening part of the transformer 4 (the −Z side) via the potting material 63 or the thermal conductance member 61 for reducing contact thermal resistance. The heat dissipation plate 92 transports heat from the transformer 4 on the side of the opening part (the −Z side), up to the potting material 63 on the side of the heat dissipation surface 301.

Accordingly, in a direction (the Z direction) orthogonal to the heat dissipation surface 301, a height H1 of the transformer assembly 2 having the heat dissipation structure 3 according to the present disclosure can be made lower than a height H2 of the transformer assembly 9 according to the comparative example that requires the heat dissipation plate 92. Specifically, according to the heat dissipation structure 3 according to the present disclosure, in the direction (the Z direction) orthogonal to the heat dissipation surface 301, it is possible to downsize the transformer assembly 2 by an amount corresponding to the thickness of the thermal conductance member 61 and the heat dissipation plate 92 without impairing a heat dissipation property of a part distant from the cooling surface 101.

Moreover, in the heat dissipation structure 3 according to the present disclosure, heat from the side (the −Z side) of the top surface 501 of the transformer 4 is routed up to the heat dissipation surface 301 by being transported by the metal case 5 from the top surface 501 up to the fixing part 51 through each side surface.

On the other hand, in the transformer assembly 9 according to the comparative example, the other end of the end thermally connected to the transformer 4 of the heat dissipation plate 92 is provided on the lateral side of the transformer 4 in order to route heat from the side of the opening part of the transformer 4 (the −Z side) up to the heat dissipation surface 301.

Accordingly, on a horizontal surface (the X-Y plane) parallel to the heat dissipation surface 301, a width W1 of the transformer assembly 2 having the heat dissipation structure 3 according to the present disclosure can be made smaller than a width W2 of the transformer assembly 9 according to the comparative example that requires the heat dissipation plate 92. Specifically, according to the heat dissipation structure 3 according to the present disclosure, on a horizontal surface (the X-Y plane) parallel to the heat dissipation surface 301, it is possible to downsize the transformer assembly 2 by an amount corresponding to the thicknesses of two heat dissipation plates 92 and the potting material 63.

In the heat dissipation structure 3 according to the present disclosure, a filling direction (−the Z direction) of the potting material 63 into the metal case 5 differs from the attachment direction (the +Z direction) of the transformer assembly 2 to the housing 11. Thus, according to the heat dissipation structure 3 according to the present disclosure, the notch 53 can be provided on the upside in the filling direction (−the Z direction) of the potting material 63 (i.e., the downside (the +Z side) in the attachment direction (the +Z direction) to the housing 11. By performing potting in the assembly process of the transformer assembly 2, it is possible to sub-unitize the transformer assembly 2. It is possible to assemble the connector 45 to the sub-unitized transformer assembly 2, and attach the sub-unitized transformer assembly 2 to the housing 11. Then, in an attachment process of the transformer assembly 2 to the housing 11, potting can be made unnecessary.

On the other hand, in the transformer assembly 9 according to the comparative example, a filling direction (the +Z direction) of the potting material 63 into the metal case 91 is identical to the attachment direction (the +Z direction) of the transformer assembly 9 to the housing 11. Thus, in the transformer assembly 9 according to the comparative example, a connection part where the transformer 4 is electrically connected to a circuit configuration of the in-vehicle charger 1 is provided on the side of the opening part (the −Z side) of the metal case 91. If the transformer assembly 9 according to the comparative example includes an approximately-cylindrical metal case 91 not having a bottom surface (flat plate part on the +Z side), the height H2 of the transformer assembly 9 in the direction (the Z direction) orthogonal to the heat dissipation surface 301 can be lower to a height nearly equal to the height H1 of the transformer assembly 2 having the heat dissipation structure 3 according to the present disclosure. Alternatively, by forming a recess-shaped bathtub structure in part of the housing 11, and filling the potting material 63 in a state where the transformer 4 is arranged in the bathtub structure, the height H2 in the direction (the Z direction) orthogonal to the heat dissipation surface 301 can be lower to a height nearly equal to the height H1 of the transformer assembly 2 having the heat dissipation structure 3 according to the present disclosure. Nevertheless, in these cases, it is necessary to perform potting in the attachment process to the housing 11.

Accordingly, according to the heat dissipation structure 3 according to the present disclosure, the connector 45 for electrically connecting the transformer 4 to the circuit configuration of the in-vehicle charger 1 can be provided on the side of the housing 11. Therefore, it is possible to improve a degree of arrangement freedom of each component in the in-vehicle charger 1. As a matter of course, in the transformer assembly 2 having the heat dissipation structure 3 according to the present disclosure, the connector 45 may be provided on the side (the −Z side) of the top surface 501. By performing potting in the assembly process of the transformer assembly 2, it is possible to sub-unitize the transformer assembly 2. It is possible to assemble the connector 45 to the sub-unitized transformer assembly 2, and attach the sub-unitized transformer assembly 2 to the housing 11. Then, in an attachment process of the transformer assembly 2 to the housing 11, potting can be made unnecessary.

The heat dissipation structure 3 according to the present disclosure pots the transformer 4 placed inside the metal case 5 formed into a box shape. Thus, according to the heat dissipation structure 3 according to the present disclosure, similarly to the case where an approximately-cylindrical metal case 91 not having a bottom surface (flat plate part on the +Z side) is not included in the transformer assembly 9 according to the comparative example, or the case where the bathtub structure is formed in part of the housing 11, it is possible to facilitate insulation from the housing 11 (i.e., facilitate insulation assuring). Since curing of the potting material 63 can be executed for each magnetic component included in the transformer assembly 2, it is possible to enhance productivity. A vacuum device for filling the potting material 63 can be made less expensive and easier to apply, and cost reduction for stable filling quality can be achieved. Moreover, a component main body placed inside the metal case 5, such as the transformer 4, can be held by the potting material 63 to be filled. Therefore, it is possible to implement a vibration countermeasure of the in-vehicle charger 1 while reducing the number of structural objects such as a support member including a mold and a fixing member.

In a case where the filling direction (−the Z direction) of the potting material 63 into the metal case 5 and the attachment direction (the +Z direction) of the transformer assembly 2 to the housing 11 are different, due to a variation in working accuracy of the core 41 of the transformer 4, assembly accuracy of the transformer 4, and working accuracy of the metal case 5, the position of each component of the transformer assembly 2 on the side (the +Z side) of the heat dissipation surface 301 might fail to fall within a range that can be regarded as one surface, or cannot be easily fall within the range. In a case where the position of each component of the transformer assembly 2 on the side (the +Z side) of the heat dissipation surface 301 does not fall within a range that can be regarded as one surface, contact thermal resistance generated when the transformer assembly 2 is attached to the housing 11 becomes large, and heat dissipation efficiency of the transformer 4 might decline. In such a situation, in the heat dissipation structure 3 according to the present disclosure, the thermal conductance member 61 is provided on the side (the +Z side) of the heat dissipation surface 301 of the transformer assembly 2 (i.e., the side of the opening part 507 of the transformer 4). With this configuration, even in a case where the filling direction (−the Z direction) of the potting material 63 into the metal case 5 and the attachment direction (the +Z direction) of the transformer assembly 2 to the housing 11 are different, it is possible to reduce contact thermal resistance to be generated when the transformer assembly 2 is attached to the housing 11.

According to at least one embodiment described above, it is possible to downsize a magnetic component such as the transformer assembly 2 provided in a coil device such as the in-vehicle charger 1 (power conversion device).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Additional Statement

By the description of the above embodiment, the following technical schemes are disclosed.

### Technical Scheme 1

A magnetic component comprising:
a component main body from which heat is to be dissipated;
a box-shaped member with a box shape whose one face is opened, the box-shaped member including a plate-like member having thermal conductivity, the box-shaped member including
   an opening part,
   a top surface facing the opening part,
   side surfaces extending from the top surface to the opening part, and
   a heat dissipation part provided at an end on a side of the opening part of one or more of the side surfaces; and
a potting material having thermal conductivity, the potting material being filled into the box-shaped member from the opening part, wherein
the top surface of the box-shaped member is thermally connected to a first principal surface of the component main body, and
the box-shaped member functions as a heat dissipation pathway through which heat is transported from the component main body to the heat dissipation part via the top surface by thermal conductance.

### Technical Scheme 2

The magnetic component according to the technical scheme 1, wherein
the heat dissipation part extends along the top surface from the end on the side of the opening part of one or more of the side surfaces, and
a surface on an opposite side of the top surface of the heat dissipation part is a heat dissipation surface.
   Technical scheme 3

The magnetic component according to the technical scheme 2, wherein
the box-shaped member is fixed to an external cooling member in a direction different from a filling direction of the potting material, the filling direction being directed from the opening part toward the top surface, and
the heat dissipation part of the box-shaped member is a fixing part fixing the box-shaped member to the external cooling member.
   Technical scheme 4

The magnetic component according to the technical scheme 2 or 3, wherein
the box-shaped member is fixed to an external cooling member in a direction different from a filling direction of the potting material, the filling direction being directed from the opening part toward the top surface, and
the heat dissipation part of the box-shaped member is a positioning part defining a position of the box-shaped member on the external cooling member.
   Technical scheme 5

The magnetic component according to any one of the technical schemes 1 to 4, further comprising a thermal conductance member with a thermal interface material, the thermal conductance member being provided on a second principal surface on an opposite side of the first principal surface of the component main body,
wherein a surface of the thermal conductance member on an opposite side of the second principal surface of the component main body and a surface on an opposite side of the top surface of the heat dissipation part are each a heat dissipation surface.

### Technical Scheme 6

The magnetic component according to any one of the technical schemes 1 to 5, wherein the potting material is filled into the box-shaped member from the opening part in a state where
the top surface of the box-shaped member is positioned below the opening part in a gravity direction, and
the component main body is placed inside the box-shaped member.

### Technical Scheme 7

The magnetic component according to any one of the technical schemes 1 to 6, wherein the potting material is filled up to a side of the opening part from an internal space of the component main body placed inside the box-shaped member.

### Technical Scheme 8

The magnetic component according to any one of the technical schemes 1 to 7, wherein one or more of the side surfaces each include a notch recessed from an end on a side of the opening part toward the top surface.

### Technical Scheme 9

The magnetic component according to the technical scheme 8, further comprising a connector placed to pass through the notch, the connector electrically connecting the component main body to an outside.

### Technical Scheme 10

The magnetic component according to the technical scheme 8 or 9, wherein the potting material is filled up to a side of the top surface from the notch.

### Technical Scheme 11

The magnetic component according to any one of the technical schemes 1 to 10, wherein the component main body is a transformer.

### Technical Scheme 12

A coil device comprising:
the magnetic component according to any one of the technical schemes 1 to 11; and
a housing including a flow path of cooling liquid running within one surface of the housing,
wherein the heat dissipation part of the magnetic component is thermally connected to the housing in a state where the magnetic component is attached to the housing.

### Technical Scheme 13

A coil device (in-vehicle charger) comprising:
electronic components including the magnetic component according to any one of the technical schemes 1 to 11,
wherein the coil device is configured to
   convert, into direct-current power, alternating-current power supplied from an external single-phase or three-phase alternating-current power supply, and
   output the converted direct-current power.

### Technical Scheme 14

The coil device (in-vehicle charger) according to the technical scheme 12, further comprising electronic components including the magnetic component,
wherein the coil device is configured to
   convert, into direct-current power, alternating-current power supplied from an external single-phase or three-phase alternating-current power supply, and
   output the converted direct-current power.

### Technical Scheme 15

A coil device (DC-DC converter) comprising:
electronic components including the magnetic component according to any one of the technical schemes 1 to 11,
wherein the coil device is configured to
   convert input alternating-current power into direct-current power with a predetermined voltage value, and
   output the converted direct-current power.

### Technical Scheme 16

The coil device (DC-DC converter) according to the technical scheme 12, further comprising electronic components including the magnetic component,
wherein the coil device is configured to
   convert input alternating-current power into direct-current power with a predetermined voltage value, and
   output the converted direct-current power.

### Technical Scheme 17

A vehicle comprising:
the coil device according to any one of the technical schemes 12 to 16; and
a battery to be charged with the direct-current power converted by the coil device.

### Technical Scheme 18

A manufacturing method of a magnetic component, the manufacturing method comprising:
placing, inside a box-shaped member, a component main body from which heat is to be dissipated, the box-shaped member being formed into a box shape whose one face is opened, the box-shaped member being formed by using a plate-like member having thermal conductivity, the box-shaped member including an opening part, a top surface facing the opening part, side surfaces extending from the top surface to the opening part, and a heat dissipation part provided at an end on a side of the opening part of one or more of the side surfaces;
filling a potting material having thermal conductivity into the box-shaped member from the opening part; and
infiltrating the potting material into the component main body, wherein
the top surface of the box-shaped member is thermally connected to a first principal surface of the component main body, and
the box-shaped member functions as a heat dissipation pathway through which heat is transported from the component main body to the heat dissipation part via the top surface by thermal conductance.

### Technical Scheme 19

A manufacturing method of a magnetic component, the manufacturing method comprising:
filling a potting material having thermal conductivity into a box-shaped member from an opening part of the box-shaped member, the box-shaped member being formed into a box shape whose one face is opened, the box-shaped member being formed by using a plate-like member having thermal conductivity, the box-shaped member including the opening part, a top surface facing the opening part, side surfaces extending from the top surface to the opening part, and a heat dissipation part provided at an end on a side of the opening part of one or more of the side surfaces;
placing, inside the box-shaped member, a component main body from which heat is to be dissipated; and
infiltrating the potting material into the component main body, wherein
the top surface of the box-shaped member is thermally connected to a first principal surface of the component main body, and
the box-shaped member functions as a heat dissipation pathway through which heat is transported from the component main body to the heat dissipation part via the top surface by thermal conductance.

### Technical Scheme 20

A manufacturing method of a magnetic component, the manufacturing method comprising:
filling a potting material having thermal conductivity into a box-shaped member from an opening part of the box-shaped member, the box-shaped member being formed into a box shape whose one face is opened, the box-shaped member being formed by using a plate-like member having thermal conductivity, the box-shaped member including the opening part, a top surface facing the opening part, side surfaces extending from the top surface to the opening part, and a heat dissipation part provided at an end on a side of the opening part of one or more of the side surfaces;
placing, inside the box-shaped member, a component main body from which heat is to be dissipated;
infiltrating the potting material into the component main body; and
additionally filling the potting material inside the box-shaped member from the opening part, wherein
the top surface of the box-shaped member is thermally connected to a first principal surface of the component main body, and
the box-shaped member functions as a heat dissipation pathway through which heat is transported from the component main body to the heat dissipation part via the top surface by thermal conductance.

What is claimed is:

1. A magnetic component comprising:
a component main body from which heat is to be dissipated;
a box-shaped member with a box shape whose one face is opened, the box-shaped member including a plate-like member having thermal conductivity, the box-shaped member including
an opening part,
a top surface facing the opening part,
side surfaces extending from the top surface to the opening part, and
a heat dissipation part provided at an end on a side of the opening part of one or more of the side surfaces; and
a potting material having thermal conductivity, the potting material being filled into the box-shaped member from the opening part, wherein
the top surface of the box-shaped member is thermally connected to a first principal surface of the component main body, and
the box-shaped member functions as a heat dissipation pathway through which heat is transported from the component main body to the heat dissipation part via the top surface by thermal conductance.

2. The magnetic component according to claim 1, wherein
the heat dissipation part extends along the top surface from the end on the side of the opening part of one or more of the side surfaces, and
a surface on an opposite side of the top surface of the heat dissipation part is a heat dissipation surface.

3. The magnetic component according to claim 2, wherein
the box-shaped member is fixed to an external cooling member in a direction different from a filling direction of the potting material, the filling direction being directed from the opening part toward the top surface, and
the heat dissipation part of the box-shaped member is a fixing part fixing the box-shaped member to the external cooling member.

4. The magnetic component according to claim 2, wherein
the box-shaped member is fixed to an external cooling member in a direction different from a filling direction of the potting material, the filling direction being directed from the opening part toward the top surface, and
the heat dissipation part of the box-shaped member is a positioning part defining a position of the box-shaped member on the external cooling member.

5. The magnetic component according to claim 1, further comprising a thermal conductance member with a thermal interface material, the thermal conductance member being provided on a second principal surface on an opposite side of the first principal surface of the component main body,
wherein a surface of the thermal conductance member on an opposite side of the second principal surface of the component main body and a surface on an opposite side of the top surface of the heat dissipation part are each a heat dissipation surface.

6. The magnetic component according to claim 1, wherein the potting material is filled into the box-shaped member from the opening part in a state where
the top surface of the box-shaped member is positioned below the opening part in a gravity direction, and
the component main body is placed inside the box-shaped member.

7. The magnetic component according to claim 1, wherein the potting material is filled up to a side of the opening part from an internal space of the component main body placed inside the box-shaped member.

8. The magnetic component according to claim 1, wherein one or more of the side surfaces each include a notch recessed from an end on a side of the opening part toward the top surface.

9. The magnetic component according to claim 8, further comprising a connector placed to pass through the notch, the connector electrically connecting the component main body to an outside.

10. The magnetic component according to claim 8, wherein the potting material is filled up to a side of the top surface from the notch.

11. The magnetic component according to claim 1, wherein the component main body is a transformer.

12. A coil device comprising:
the magnetic component according to claim 1; and
a housing including a flow path of cooling liquid running within one surface of the housing,
wherein the heat dissipation part of the magnetic component is thermally connected to the housing in a state where the magnetic component is attached to the housing.
